(19) United States
(12) Patent Application Publication
(10) Pub. No.: US 2015/0184896 A1
(43) Pub. Date: Jul. 2, 2015

(54) SOLAR PANEL SUPPORT APPARATUS

(71) Applicant: RI Enterprises, LLC, San Marcos, CA (US)

(72) Inventors: Lawrence D. Lippert, Oceanside, CA (US); Michael Jason Ianni, Vista, CA (US); Dustin K. Rosepink, Mission Viejo, CA (US); Jon E. Krivokopich, San Marcos, CA (US); Chad S. Hart, San Marcos, CA (US)

(73) Assignee: RI Enterprises, LLC, San Marcos, CA (US)

(21) Appl. No.: 14/146,692

(22) Filed: Jan. 2, 2014

(51) Int. Cl. F24J 2/52; H01L 31/042; F16B 2/02

(52) U.S. Cl. CPC F24J 2/5243; F16B 2/02; H01L 31/0422

(57) ABSTRACT

A support apparatus for securing a row of solar panels to a support structure may include a fastener extending between and attaching an elongated clamp rail to a purlin. The fastener has a first non-rotatable end portion. A rotatable member is connected to a second end portion of the fastener for causing, when rotated, the clamp rail to close onto upper marginal edges of the row of solar panels along a continuous line of engagement therewith to help secure the solar panels in place on the purlin.

### RELATED APPLICATION

The present patent application is related to U.S. patent application entitled SOLAR PANEL MOUNTING METHODS, filed Jan. 2, 2014, and assigned application Ser. No. ______, which is incorporated herein by reference as if set forth herein in its entirety.

### FIELD OF THE INVENTION

The present invention relates to a solar panel support apparatus. It more particularly relates to such an apparatus that allows a safer and easier way to mount solar panels in an array in a more secure manner

### BACKGROUND ART

This section describes the background art of the disclosed embodiments of the present invention. There is no intention, either express or implied, that the background art discussed in this section legally constitutes prior art.

Solar panel arrays have been constructed by installing them on purlins mounted on top of a foundation system or support structure, which may include a series of posts and other components to support the arrays high off of the ground. For example, the solar panel arrays may be mounted on top of car ports, canopies, photovoltaic structures and others. The solar panels may be connected electrically to feed the generated power to an electric power grid.

Conventional methods and systems of mounting solar panels to purlins typically employ a plurality of small individual edge clips that must be inserted in place and then driven with a tool to fasten the clips to the support structure in the field by an installer to tighten down the solar panels on the purlins. The individual edge clips are fastened in place to secure the solar panels to the support structure. This mounting process is slow and labor intensive, and thus expensive to install.

Additionally, for at least some applications, the installer must assemble four individual edge clips for each solar panel, two on each end of the panel. Thus, there are only four points of attachment to the support structure. Such a technique may not be entirely satisfactory for certain applications, such as high slope structures (e.g., 20 degrees or 30 degrees) as well as locations where there may be high winds or other harsh weather or other conditions.

For example, reference may be made to the following patents; U.S. Pat. No. 8,418,983; Germany Patent Publication No. DE202012005671; PCT Patent Publication No. WO10100376; Germany Patent Publication No. DE202009004746; U.S. Pat. No. 8,256,169; PCT Patent Publication No. WO10071085; U.S. Pat. No. 7,766,292; PCT Patent Publication No. WO11154019; PCT Patent Publication No. WO12104455; Germany Patent Publication No. DE202007012570; U.S. Patent Publication No. 2007/084504; U.S. Patent Publication No. 2012/267490; and U.S. Patent Publication No. 2012/175322. Reference is also made to the “Powers' Slide-in Solar Purlin” as shown at the website address: http://powersteel.com/solar/solar-purlin.html.

In addition, the placement of the solar panels and fastening them down by means of many separate small edge clips is conventionally done from above the array, while leaning over from a lift or standing on the rail of the lift. The installer is thus required to perform this task in a less than safe manner as compared to standing on the ground or other safe location. By undertaking the work from an elevated position in a conventional lift, the installer can fall from the lift and sustain serious injuries. Also, such an unsafe installation technique which places the installer at risk, may be a violation of governmental safety regulations such as the Occupational Safety and Health Administration federal regulations, and possibly others.

Further, when an inoperable panel requires replacement in conventional systems, the installer must again position themselves above the array in order to loosen the edge clips, take out the inoperable panel, insert a new panel, and then tighten back down each one of the edge clips. Furthermore, at least some conventional systems require that some or all of the adjacent solar panels be removed during the installation of a single new panel. Additionally, in some situations where the malfunctioning solar panel is located in the center of the array of panels, the installer may have to walk on the array of panels in a very unsafe manner to gain access to the panel to be replaced.

### BRIEF DESCRIPTION OF THE DRAWINGS

In order to better understand the invention and to see how the same may be carried out in practice, non-limiting preferred embodiments of the invention will now be described with reference to the accompanying drawings, in which:

FIG. 1 is a side view of a solar panel system including a solar panel purlin assembly constructed according to an embodiment;

FIG. 2A is a side view of a middle clamp purlin of the solar panel purlin assembly of FIG. 1;

FIG. 2B is a side view of a top clamp rail of the solar panel purlin assembly of FIG. 1;

FIG. 2C is a side view of a bottom clamp rail of the solar panel purlin assembly of FIG. 1;

FIG. 3 is a side view of a clamp apparatus of the solar panel purlin assembly of FIG. 1;

FIG. 3A is a top view of a clamp apparatus of the solar panel purlin assembly of FIG. 1;

FIGS. 4A-D illustrates a side view of an installation of a solar panel on the purlin assembly of FIG. 1;

FIG. 5 illustrates a side view of a clamp apparatus of the solar panel purlin assembly according to an embodiment;

FIG. 6 illustrates a side pictorial view of a solar panel purlin assembly according to an embodiment;

FIG. 7 illustrates a side pictorial view of a solar panel purlin assembly according to an embodiment;

FIG. 8 illustrates a side pictorial view of a solar panel purlin assembly including a fastening device having a stop member;

FIG. 9 is a flowchart illustrating a method of securing solar panels on a purlin according to an embodiment;

FIG. 10 is a flowchart illustrating a method of making clamp apparatus according to an embodiment; and

FIG. 11 is a flowchart illustrating a method of making solar panel support apparatus according to an embodiment.

### DETAILED DESCRIPTION OF CERTAIN EMBODIMENTS

Certain embodiments of the present invention will now be described more fully hereinafter with reference to the accompanying drawings, in which some, but not all, embodiments of the invention are shown. Indeed, these embodiments of the invention may be in many different forms and thus the invention should not be construed as limited to the embodiments set forth herein; rather, these embodiments are provided as illustrative examples only so that this disclosure will satisfy applicable legal requirements. Like numbers refer to like elements throughout.

It will be readily understood that the components of the embodiments as generally described and illustrated in the drawings herein, could be arranged and designed in a wide variety of different configurations. Thus, the following more detailed description of certain ones of the embodiments of the apparatus, system, components and methods of the present invention, as represented in the drawings, is not intended to limit the scope of the invention, as claimed, but is merely representative examples of one or more of the embodiment of the invention.

A support apparatus for securing a row of solar panels to a support structure may include a fastener extending between and attaching an elongated clamp rail to a purlin. The fastener has a first non-rotatable end portion. A rotatable member is connected to a second end portion of the fastener for causing, when rotated, the clamp rail to close onto upper marginal edges of the row of solar panels along a continuous line of engagement therewith to help secure the solar panels in place on the purlin.

A support apparatus for securing at least one solar panel to a support structure is constructed in accordance with another embodiment. The support apparatus may include a fastener attached at its upper end to a clamp rail in a non-rotatable manner and adapted to be installed at its lower end to a purlin. A resilient spacer holds the clamp rail open to receive a solar panel marginal edge and is compressed when rotating a rotatable member on the bottom portion of the fastener from below the solar panel to close the clamp rail onto an upper marginal edge of the at least one solar panel along a continuous line of engagement therewith.

According to another embodiment, a clamp apparatus for securing at least one solar panel to a purlin may include a fastener attached at its upper end portion to the underside of a clamp rail in a generally non-rotatable manner and having a rotatable member at its lower end portion. A resilient spacer helps to position the clamp rail in its opened position to provide a panel receiving opening above a panel receiving surface of the purlin. The resilient spacer compresses responsive to driving the rotatable member of the fastener from below the solar panel to cause the clamp rail to close and thus to engage an upper marginal edge of the at least one solar panel along a continuous line of engagement therewith, to secure it in place on the purlin.

Another embodiment relates to a support apparatus for securing at least one solar panel to a support structure. The support apparatus may include clamp apparatus for mounting above a purlin to secure the at least one solar panel on top of the purlin. The clamp apparatus includes a clamp rail and a series of fastening devices. Each fastening device includes a fastener attached at its upper end to the clamp rail in a generally non-rotatable manner and attached to an upper surface of the purlin. The fastening device further includes a rotatable member at its lower end. A resilient spacer helps to position the clamp rail in its opened position to provide a panel receiving opening above a panel receiving surface of the purlin. The resilient spacer compresses in response to driving the rotatable member of the fastener from below the solar panel to cause the clamp rail to close and thus to engage an upper marginal edge of the at least one solar panel along a continuous line of engagement therewith, to secure the at least one solar panel in place on the purlin.

Therefore, according to at least one embodiment, an installer can safely tighten down an array of solar panels from a safe position such as standing on the ground, in a quick and easy manner. Also, for some applications, the installer can also still be safely positioned in the lift (not shown) and be able to tighten from underneath the array of panels. These novel techniques eliminate, or greatly reduce the possibility of endangering the safety of the installer attempting to install conventional edge clips from unsafe heights.

According to an embodiment, there is provided approximately two fastening devices per panel along a clamp rail. The fastening devices can quickly and easily be tightened to secure the clamp rail into a continuous line of engagement with a marginal edge of either one solar panel or two adjacent solar panels. This is in sharp contrast to conventional techniques where the installer must both install and tighten four small individual clips for securing each panel in place. With the present embodiments, no installation of edge clips is required, since the support apparatus may all be assembled in the factor and not at the job site. Also, there may be only about half as many fastening manipulations required, since there are about half as many fastening devices employed per solar panel as compared to conventional edge clips. Thus, the time to assemble the solar panel array at a given job site is dramatically reduced as compared to conventional mounting techniques, and therefore the overall cost of the project is significantly reduced accordingly.

Additionally, by utilizing the solar panel support apparatus, the solar panels are held much more securely in place. According to an embodiment, a pair of clamp rails may be used to secure the opposite marginal edges of each panel along a continuous line of engagement therewith. This technique enables a much more secure attachment of the panels to the underlying purlin, as compared to single points of attachment by edge clips.

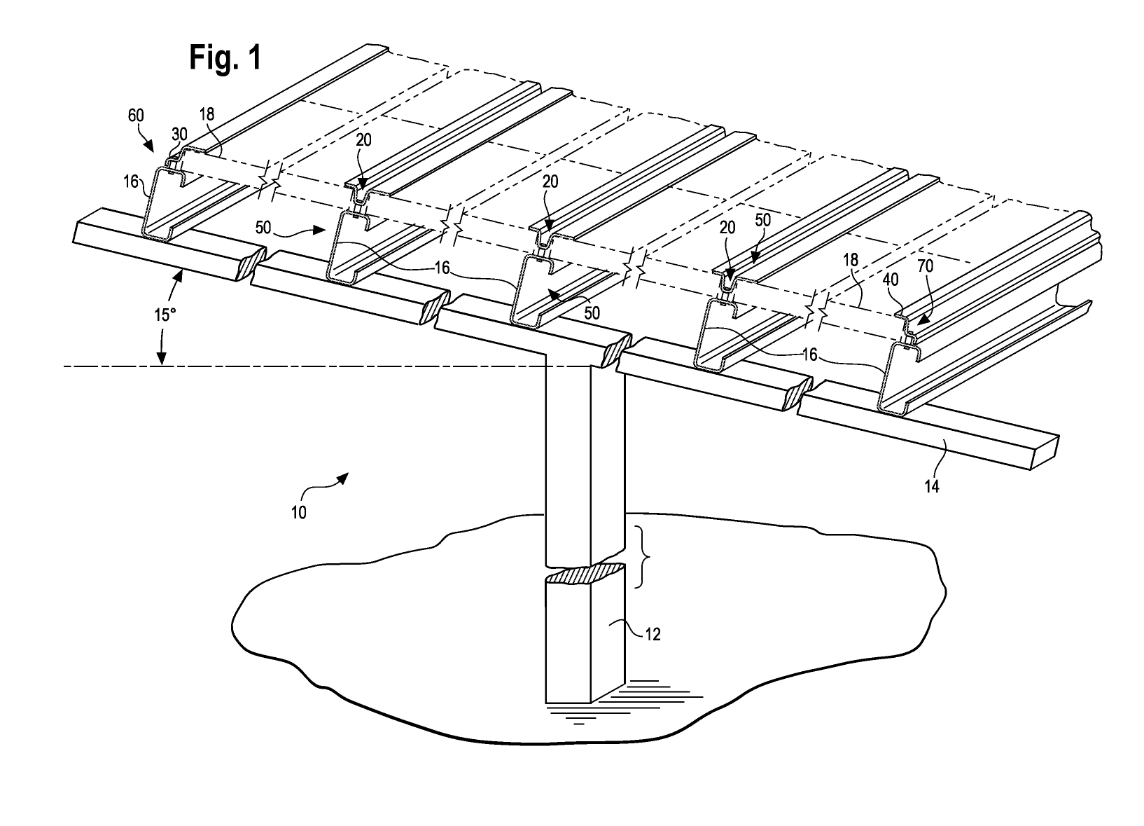

Referring now to the drawings, and more particularly to FIG. 1 thereof, a solar panel support apparatus or structure 10 may be constructed according to an embodiment and includes a plurality of purlins or beams such as C-shape purlins 16 connected generally horizontally to a variety of elongated clamp rails 20, 30 and 40 forming a part of respective clamp apparatus 50, 60 and 70. The support apparatus 10 may be fabricated and assembled in the factory and then may be mounted on top of a desired support structure 13, which may include posts or columns such as a post 12 and beams such as a beam 14 erected at the site for the solar panel support system 10. It should be understood that other types and kinds of support structures may also be employed.

In other embodiments, the purlins may have other shapes such as a Z-shape purlin (not shown) or any other shape that allows access to the top of the purlin from the side and/or below the purlin. Individual solar panels 18 may be installed between the clamp apparatus 50, 60 and 70 and the purlins 16. The clamp apparatus 50, 60 and 70 including the mounted solar panels 18 may be inclined at an angle to achieve maximum or at least more favorable total energy output for the entire solar panel array purlin assembly 10. This tilt angle may range from about 2 degrees to about 45 degrees, and more preferably from about 10 degrees to about 20 degrees, depending upon location and application of the solar panel system 10. One example as indicated in the drawings may be about 15 degrees as shown in the drawings.

The dimensions of one conventional type of solar panel 18 may be approximately 65 inches by about 39 inches by about 2 inches. Other types and sizes of solar panels may also be usable with the support apparatus of the present embodiments. The clamp apparatus 50, 60 and 70 may be prefabricated and preassembled of a metal material such as galvanized steel, aluminum or other suitable materials.

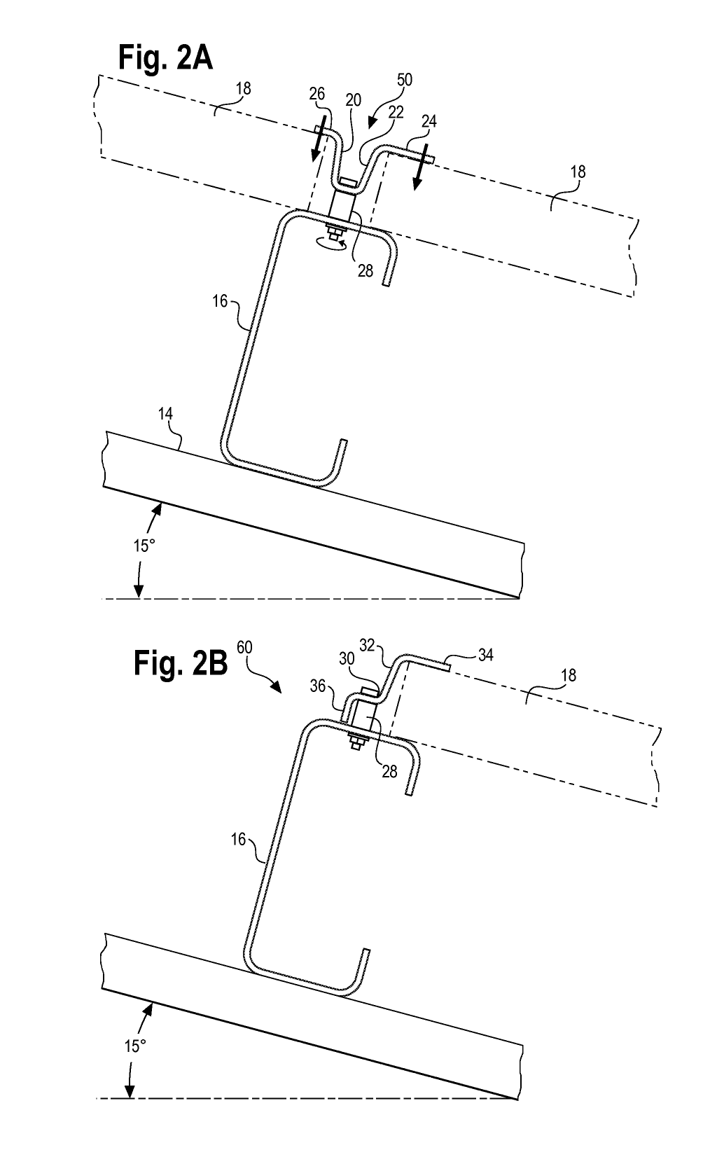

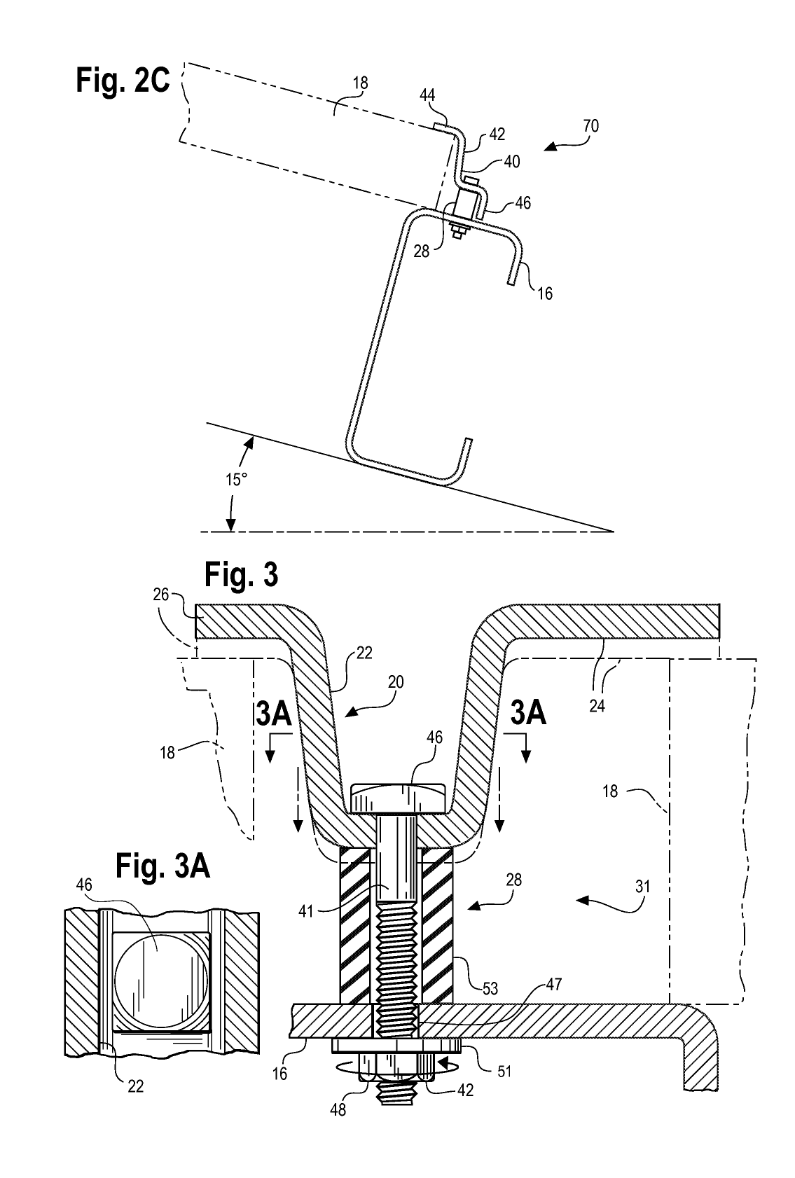

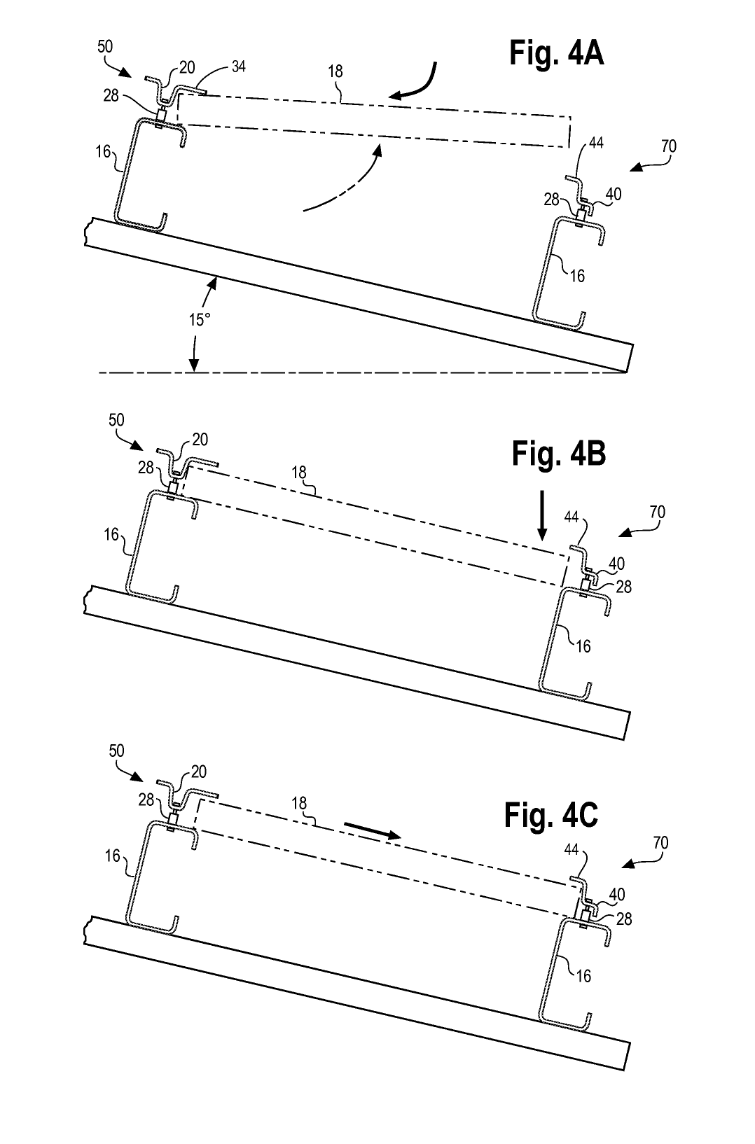

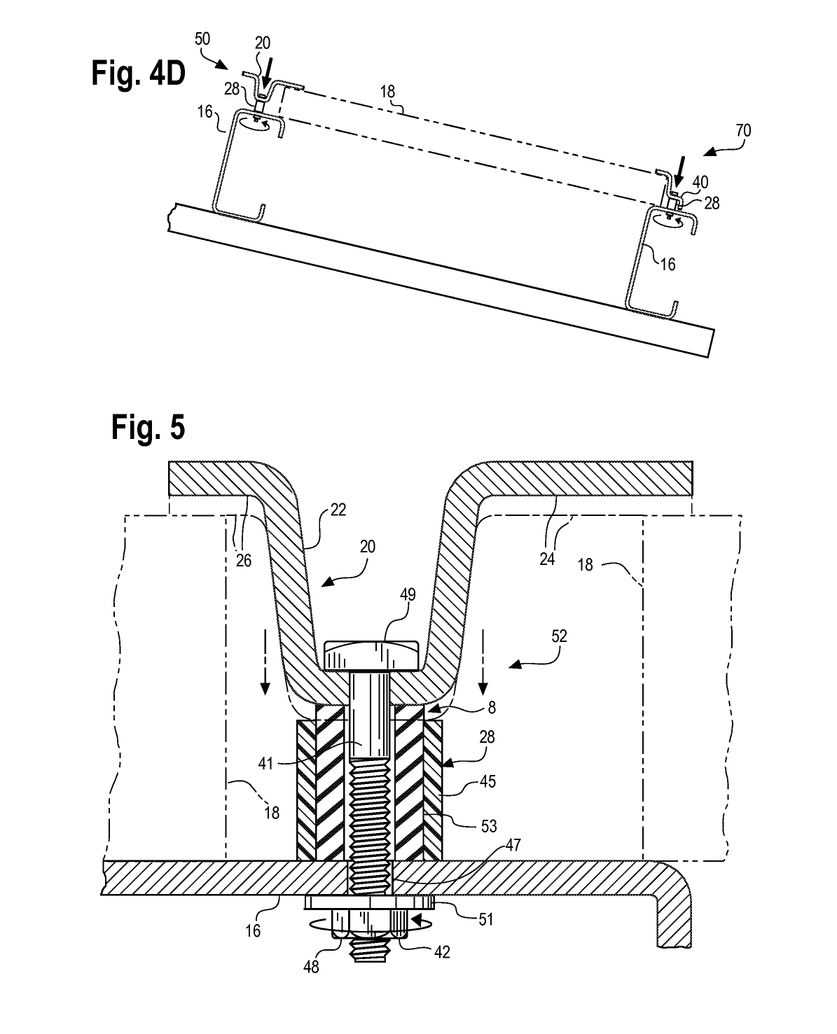

As shown in FIGS. 2A-C, the clamp rails may include at least three distinct types: a middle clamp rail 20 (FIG. 2A), a top clamp rail 30 (FIG. 3A) and a bottom clamp rail 40 (FIG. 4A) which operate similarly. FIG. 2A shows a middle clamp apparatus 50 mounted on top of a purlin 16, which in turn is connected on top of a beam 14. The clamp apparatus 50 may include a middle clamp rail 20 connected to a C-shape purlin 16 by means of a series of spaced apart fastening devices 28.

The middle elongated clamp rail 20 may be a one-piece rail and may include a U-shape section 22 having a short upwardly extending flange 26 and a long downwardly extending flange 24. The flanges extend outwardly in a common plane from the top of U-shape section 22. Both the short flange 26 and a long flange 24 are designed to hold down adjacent solar panels 18 onto the top of the C-shape purlin 16 during final installation to help form an array of solar panels. The flanges 24 and 26 engage upper marginal edges of the adjacent panels along continuous lines of engagement. The U-shaped section 22 may be connected to the C-shape purlin 16 with a series of spaced apart fastening devices 28 for causing the clamp rail 20 to move into engagement with the adjacent panels 18 to secure them in substantially a common plane.

FIG. 2B shows a top clamp apparatus 60 including a top clamp rail 30 connected to a C-shape purlin 16. The top clamp apparatus 60 is adapted to receive and secure in place a top end solar panel 18 as shown in FIG. 2B of the drawings.

The top clamp rail 30 may include a W-shaped section 32 having a long flange 34 and a leg flange 36. The long flange 34 extends downwardly outwardly in a parallel direction to the panel engaging top surface of the purlin 18, to form one side of the W-shape portion and is designed to press downwardly against an end marginal edge of a top end solar panel 18 of a solar panel array and against the top of the C-shape purlin 16. The leg flange 36 extends downwardly to form the other side of the W-shaped portion and serves to stabilize the clamp rail 20 when it is closed against the panel 18 as shown. The W-shaped section 32 may be connected to the C-shaped purlin 16 with a series of spaced apart fastening devices 28. During final installation, the leg flange 36 is designed to press against the panel engaging upper surface of the C-shape purlin 16 as the fastening device 28 is being tightened from below such that the long flange 34 is forced downward against an upper marginal edge of the solar panel 18 along a continuous line of engagement therewith.

FIG. 2C shows a bottom clamp apparatus 70 including a bottom clamp rail 40 connected to a C-shape purlin 16 by means of a fastening device 28. The top clamp rail 40 may include a W-shape section 42 having a short panel engaging flange 44 and a purlin engaging leg flange 46. The short flange 44 extends upwardly outwardly in a direction parallel to the upper panel engaging surface of the purlin 16, to form one side of the W-shape portion and is designed to engage forcibly a solar panel 18 along its upper marginal edge against the top of the C-shape purlin 16. The leg flange 46 extends downwardly to form the other side of the W-shape portion. The W-shaped section 42 may be connected to the C-shape purlin 16 with a series of spaced apart fastening devices 28 to cause the leg flange 46 to press against the C-shape purlin 16 to stabilize the clamp apparatus 70 when the fastening device 28 is tightened to cause the short flange 44 to be forced downwardly into engagement with the upper marginal edge of the bottom end solar panel 18.

FIG. 3 shows a middle clamp rail apparatus 31 that may include a middle clamp rail 20 and a fastening device 28 that may connect the middle clamp rail 20 and a C-shape purlin 16. The fastening device 28 may include a bolt 41 having a square head 49, a rotatable member such as a nut 48, and a washer 51. In order to connect the middle clamp rail 20 to the C-shape purlin, the bolt 40 is inserted through an opening or hole 47 located in the bottom of the U-shape section 22. After insertion, the washer 51 and nut 48 are engaged onto the bolt 40 from below the top of the C-shape purlin 16. As shown in FIG. 3A, the head 49 is substantially square in shape and is designed so that after insertion through the opening or hole 47 at the bottom of the U-shape section 22, the bolt 40 will not substantially rotate while tightening the nut 48 onto the bolt 41.

In another embodiment (not shown), the fastening device 28 may be reversed so that the nut 48 is captured within the bottom of the U-shape section 22 and the bolt 41 having a head 49 may be a rotatable member disposed below the C-shape purlin 16. In this embodiment, the nut 48 is designed to be captured so as not to substantially rotate while tightening, when rotating the bolt 41 from below the solar panels. Thus the bold head may be rotated from the ground or other safe location to close the clamp device onto the margin edge of at least one solar panel.

As best seen in FIG. 3, the fastening device 28 includes a fastener in the form of the bolt 41 and a rotatable member in the form of a nut 48. The fastening device 28 may also have a resilient spacer in the form of a resilient sleeve 53 that surrounds the bolt 41. The resilient spacer is designed to provide a suitable distance between the middle clamp rail 20 and the upper solar panel engaging surface of the C-shape purlin 16 when the clamp apparatus is open, before the solar panel 18 is installed in place. The resilient sleeve 53 is substantially tubular in shape and may be made of a suitable resilient material such as rubber. It should be understood that the resilient spacer may be composed of different resilient materials including synthetic rubbers, elastomers and others. Also, metal springs (not shown) such as coil springs, leaf springs and others may also be employed in place of the resilient sleeve 53.

After a solar panel 18 is installed on either or both sides of the fastening device 28, the bolt 48 is tightened by an installer from below the solar panel while standing on the ground or other safe location, to force the middle clamp rail 20 downwardly thus compressing the resilient sleeve 53 until the solar panel 18 is held firmly in place.

Similarly, a top clamp rail apparatus and a bottom clamp rail apparatus may include W-shaped sections and a fastening device 28 that may connect a W-shaped section 32 and a W-shaped section 42 respectively to a C-shape purlin. Also, the C-shaped purlin or other similar purlin (not shown) may be designed to permit easy accessed to the rotatable member such as the bolt 48 by a suitable conventional tool (not shown) used by an installer.

FIGS. 4A-D show an installation of a solar panel 18 on a support structure that includes a middle clamp apparatus 50 and a bottom clamp apparatus 70. In FIG. 4A, one end of a solar panel 18 is slid into the open middle clamp apparatus 50 such that the long flange 34 receives the end of the solar panel 18 under it and above the upper panel receiving surface of the purlin 16.

Next, as shown in FIGS. 4B and 4C the other end of the solar panel 18 is swung downwardly manually from above the panel array by the installer standing safely on the ground or other safe location, to enable the other end to move into the open bottom clamp apparatus 70 such that the short flange 44 starts to overlie the opposite upper marginal edge of the solar panel 18 as best seen in FIG. 4B. It should be understood that this entire installation procedure may either be undertaken from below or from above the solar panel array.

As shown in FIG. 4C, the panel 18 then slides downwardly under the force of gravity into further engagement with the lower clamp rail 40. Finally, as shown in FIG. 4D, the fastening devices 28 are tightened so that the middle clamp apparatus 50 and the bottom clamp apparatus 70 are tightened down along continuous lines of engagement against the solar panel 18 to hold it firmly in place against an upper purlin and the lower most purlin 16.

As shown in FIG. 1, during and after installation, the uppermost top clamp apparatus 60 is designed to be mounted at the uppermost top end of the downwardly sloping support structure while the bottommost clamp apparatus 70 is designed to be mounted at the lower end of the structure. The installation of a solar panel 18 on a support structure that includes a middle clamp apparatus 50 and a top clamp apparatus 60 may be similar to that shown in FIGS. 4A-D.

FIG. 5 shows another embodiment of the clamp rail apparatus 52 which is similar to the previously described clamp apparatus, except that the apparatus 52 can be used in the middle as well as the end solar panels of an array and still have stability without having an adjacent solar panel to bear down against. Thus, there would be no need to have separately designed different end clamp apparatus.

In this embodiment, the fastening device further includes a stop in the form of a rigid sleeve 45 that surrounds telescopically resilient sleeve 53. The rigid sleeve may be made of a rigid material such as PVC pipe or other suitable rigid load bearing material. After a solar panel 18 is installed on either or both sides of the fastening device 28, nut 42 may be tightened from below by an installer from through opening 47 in the C-shape purlin 16 which forces the middle clamp rail 20 downward thus compressing the resilient sleeve 53 onto the upper marginal edge or edges of solar panel 18. In this embodiment, the downward motion of the middle clamp rail 20 is stopped when contacting the rigid sleeve 45.

The rigid sleeve 45 is designed to provide additional stability to the clamp rail apparatus 31. This embodiment of the clamp rail apparatus 31 may be employed as shown in FIG. 5 at a middle location in an array of solar panels, but it may also be particularly useful for the top clamp rail apparatus or the bottom clamp rail apparatus typically located on the ends of the array.

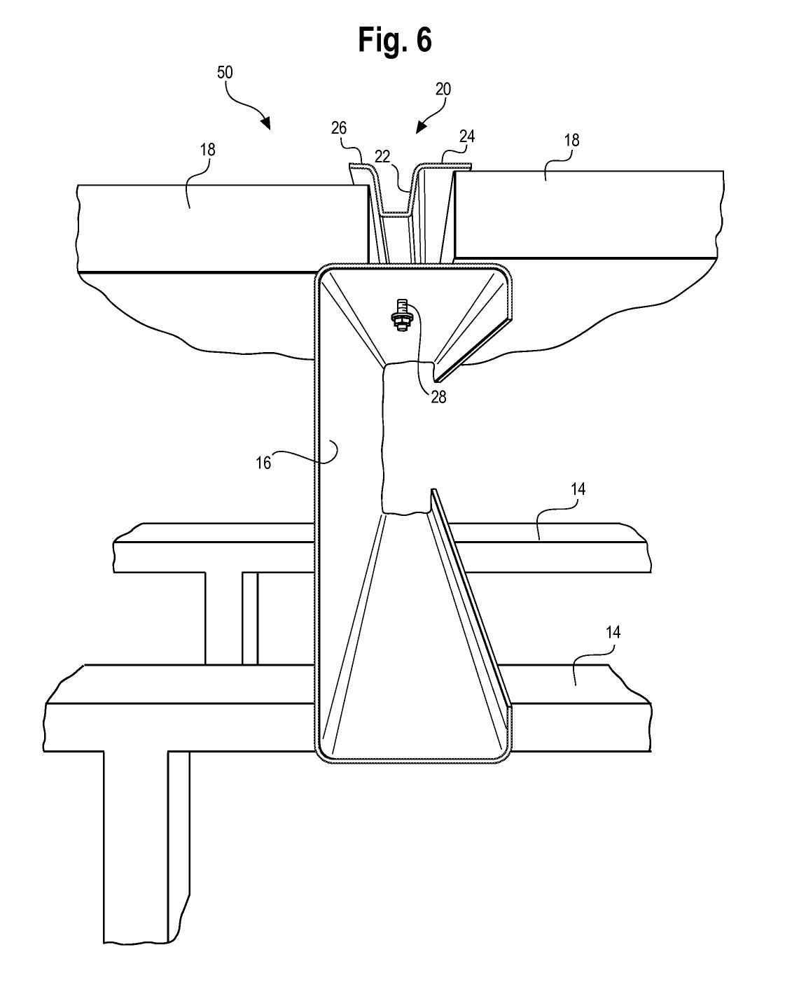

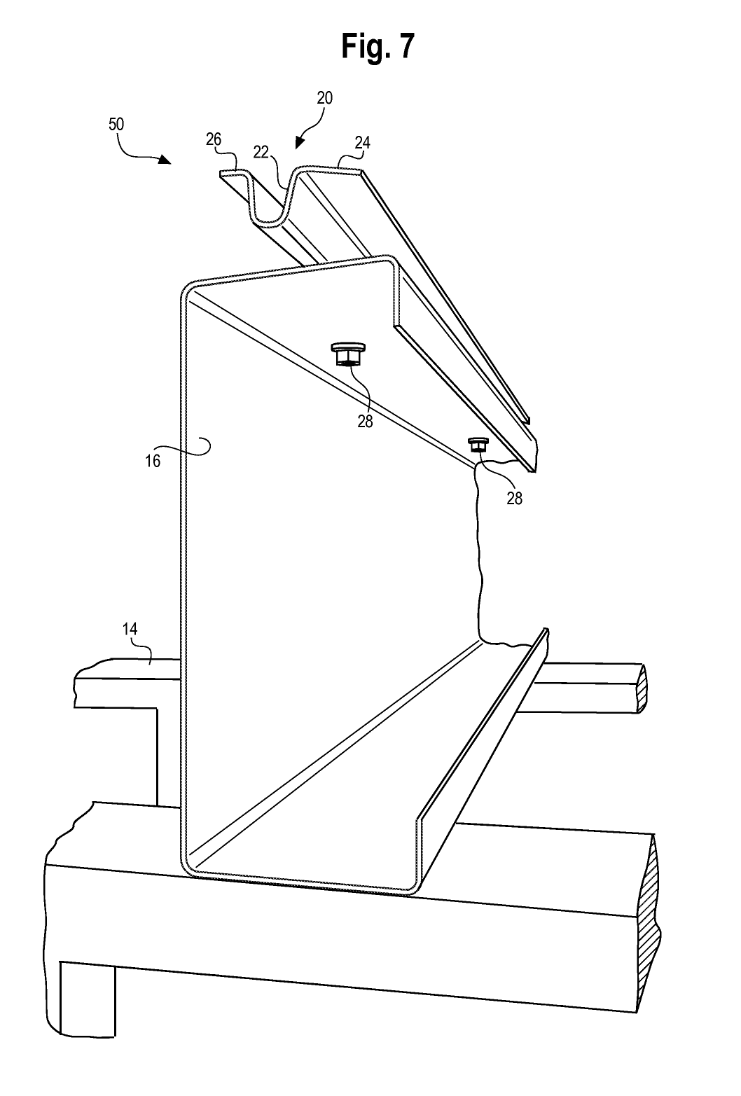

FIGS. 6 and 7 illustrates end views of an installation of a solar panel purlin assembly including a middle clamp apparatus 50 having a middle clamp rail 20 connected with fastening device 28 to purlin 16. As shown in FIG. 7, an embodiment of the purlin assembly employs the use of two of a series of fastening devices 28 spaced apart by a distance such that there will be about two fastening devices 28 for each solar panel 18. In this regard, the spacing for conventional solar panels should be between about 2 feet and about 4 feet, and most preferably about 3 feet. Also, the solar panels can be mounted either landscape or portrait, and the same spacing may be employed to achieve having about two fastening devices for each panel.

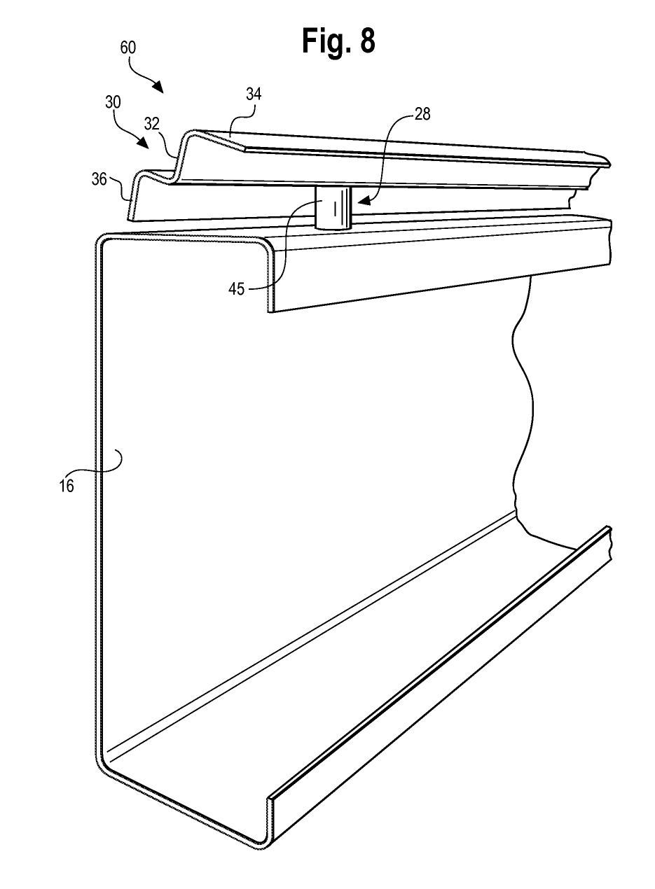

FIG. 8 illustrates a side view of a solar panel purlin assembly including a C-shape/top clamp rail purlin assembly 60 having a top clamp rail 30 connected to a C-shape purlin 16. This embodiment further includes a stop in the form of rigid sleeve 45 and shows the top clamp rail 30 compressed to a stopped position adjacent to the rigid sleeve 45 on the fastening device 28 (a solar panel is not shown).

### Mounting Methods

Referring now to FIG. 9, there is shown a method 100 of securing solar panels on a purlin. Referring to box 102, solar panels may be initially positioned onto a purlin such as purlin 16 as indicated in FIGS. 4A, 4B, 4C and 4D. As shown in box 104, a downward force may be applied distributed along an upper marginal edge of a solar panel such as solar panel 18 shown in FIG. 4D. As indicated in box 106, the solar panel 18 may then be fastened from below by moving a clamp rail such as a clamp rail 20 into a continuous line of engagement with an upper marginal edge of the solar panel 18. Referring to box 108, a second force may be applied simultaneously to an upper marginal edge of an adjacent solar panel as indicated in FIG. 5. In this manner, by merely fastening a series of fastening devices 28 below the solar panels, it is possible to tighten down adjacent panels simultaneously in a side-by side relationship.

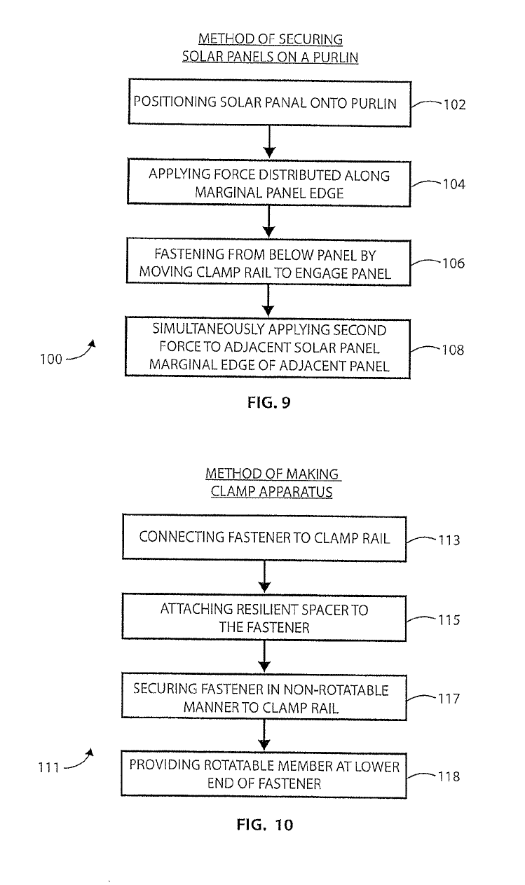

Referring now to FIG. 10, there is shown a method 111 of making a clamp apparatus for solar panels. As indicated in box 113, at least one fastener may be attached to the underside of a clamp rail as best seen in FIGS. 3 and 5. As indicated in box 115, a resilient spacer may be attached to the fastener is shown in FIGS. 3 and 5, whereby the tubular resilient spacer such as the spacer 53 surrounds the bolt 41 of the fastening device 28. As shown in box 117, the fastener such as the bolt 41 may be secured in a generally non-rotatable manner by having its square shaped head 46 disposed within the U-shaped section 22 of the clamp rail such as the clamp rail 20. Referring to box 118, a rotatable member such as a nut 42 as shown in FIGS. 3 and 5 may be driven by a suitable tool (not shown) to cause the clamp rail to move toward an upper panel engaging surface of the purlin to clamp an upper marginal edge of the panel or panels therebetween.

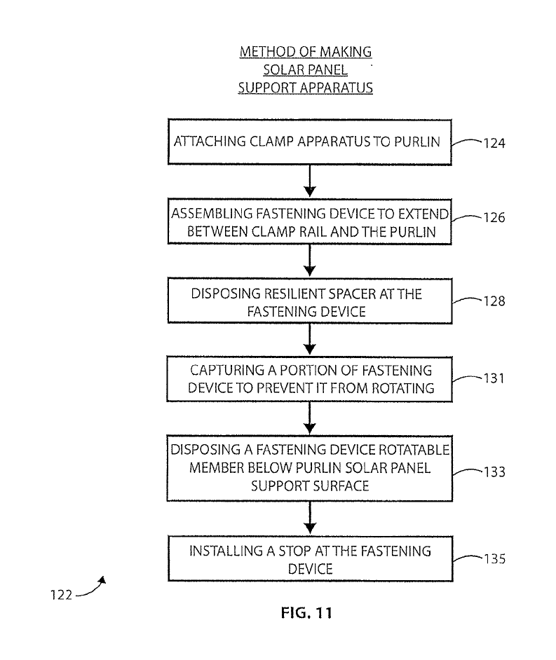

Referring now to FIG. 11, there is shown a method 122 of making solar panel support apparatus for securing a solar panels in place on to a support structure. Referring now to box 126, a clamp apparatus such as the clamp apparatus 50, may be attached to a purlin such as purlin 16. As indicated in box 126 fastening devices such as devices 28 may be assembled to extend between the clamp rail and the purlin. The devices may be spaced apart along the underside of the purlin. As indicated in box 128, resilient spacer's such as the resilient sleeves 53 may be disposed at the fastening devices. The spacers may be positioned in a telescoping surrounding disposition relative to the fasteners. Referring to box 131, a portion of the fastening devices may be captured within the clamp rail to prevent the upper portion of the fastening devices from rotating. As indicated in box 133, rotatable members or devices such as nuts 48 may be positioned onto the fastening devices below the purlin solar panel support surfaces. Finally, as indicated in box 135, a stop in the form of a rigid sleeve 45 may be attached to each fastening device to limit the movement of the clamp rail toward the purlin.

Although the invention has been described with reference to the above examples, it will be understood that many modifications and variations are contemplated within the true spirit and scope of the embodiments as disclosed herein. Many modifications and other embodiments will come to mind to one skilled in the art to which the invention pertains having the benefit of the teachings presented in the foregoing descriptions and the associated drawings. Therefore, it is to be understood that the invention shall not be limited in any way to the specific embodiments disclosed herein or modifications thereof, and that modifications and other embodiments are intended and contemplated to be included within the scope of the appended claims. Although specific terms are employed herein, they are used in a generic and descriptive sense only and not for purposes of limitation.

What is claimed is:

1. A clamp apparatus for securing at least one solar panel to a purlin, comprising:
a clamp rail;
a fastener attached at its upper end portion to the underside of the clamp rail in a generally non-rotatable manner and having a rotatable member at its lower end;
a resilient spacer for helping to position the clamp rail in its open position to provide a panel receiving opening above a panel receiving surface of the purlin; and
wherein the resilient spacer compresses responsive to driving the rotatable member of the fastener from below the solar panel to cause the clamp rail to close and thus to engage an upper marginal edge of at least one solar panel along a continuous line of engagement therewith, to secure the at least one solar panel in place on the purlin.

2. The apparatus according to claim 1, wherein the clamp rail is substantially U-shaped including a short flange attached a first top end of the U-shape and a long flange attached to a second top end of the U-shape.

3. The apparatus according to claim 1, wherein the clamp rail is substantially W-shaped including a short solar panel engageable flange to form the top end of the W-shape and a leg extension to form the bottom end of the W-shape.

4. The apparatus according to claim 1, wherein the clamp rail is substantially W-shaped including a long flange to form the top end of the W-shape and a leg extension to form the bottom end of the W-shape.

5. The apparatus according to claim 1, wherein the fastener further comprises a bolt for attaching to the rotatable member.

6. The apparatus according to claim 5, wherein the bolt further comprises a substantially square head.

7. The apparatus according to claim 1, wherein the resilient spacer is tubular in shape and composed of rubber.

8. The apparatus according to claim 1, wherein the clamp apparatus further includes:
a rigid member surrounding the resilient spacer; and
wherein the rigid member limits the compression of the resilient member when driving the rotatable member from below the solar panel.

9. The apparatus according to claim 8, wherein the rigid member comprises PVC material.

10. A support apparatus for securing at least one solar panel to a support structure, comprising:
a purlin;
clamp apparatus for mounting above the purlin to secure the at least one solar panel on top of the purlin;
the clamp apparatus including a clamp rail and a series of fastening devices;
each fastening device including a fastener attached at its upper end to the clamp rail in a generally non-rotatable manner and attached to an upper surface of the purlin;
the fastening device further including a rotatable member at its lower end;
a resilient spacer for helping to position the clamp rail in its open position to provide a panel receiving opening above a panel receiving surface of the purlin; and
wherein the resilient spacer compresses responsive to driving the rotatable member of the fastener from below the solar panel to cause the clamp rail to close and thus to engage an upper marginal edge of the at least one solar panel along a continuous line of engagement therewith, to secure the at least one solar panel in place on the purlin.

11. The support apparatus according to claim 10, wherein the clamp rail is substantially U-shaped including a short flange attached a first top end of the U-shape and a long flange attached to a second top end of the U-shape.

12. The support apparatus according to claim 10, wherein the clamp rail is substantially W-shaped including a short flange to form the top end of the W-shape and a leg extension to form the bottom end of the W-shape.

13. The support apparatus according to claim 10, wherein the clamp rail is substantially W-shaped including a long flange to form the top end of the W-shape and a leg extension to form the bottom end of the W-shape.

14. The support apparatus according to claim 10, wherein the fastener further comprises a bolt for attaching to the rotatable member.

15. The support apparatus according to claim 14, wherein the bolt further comprises a substantially square head.

16. The support apparatus according to claim 10, wherein the resilient spacer is tubular shaped and is composed of rubber.

17. The support apparatus according to claim 10, further including:
a rigid member surrounding the resilient spacer; and
wherein the rigid member limits the compression of the resilient member when driving the rotatable member from below the solar panel.

18. The support apparatus according to claim 17, wherein the rigid member comprises PVC material.

19. The support apparatus according to claim 10, wherein the purlin is a C-shaped purlin.

20. The support apparatus according to claim 10, wherein the fastening devices are spaced along the underside by a distance of between about two feet and about four feet.

21. A clamp apparatus for helping secure a row of adjacent solar panels to a purlin, comprising:
an elongated clamp rail mounted on the purlin for extending along adjacent marginal edges of the row of solar panels;
a fastener extending between and attaching the clamp rail to the purlin, the fastener having a first non-rotatable end portion; and
a rotatable member connected rotatable to a second end portion of the fastener for causing, when rotated, the clamp rail to close and thus to engage an upper marginal edge of the row of solar panels along a continuous line of engagement with the solar panels, to help secure the solar panels in place on the purlin.
